(19) United States
(12) Patent Application Publication
(10) Pub. No.: US 2011/0139611 A1
(43) Pub. Date: Jun. 16, 2011

(54) Apparatus for Fabricating Thin Film Transistor

(75) Inventors: Beong-Ju Kim, Yongin-City (KR); Ji-Su Ahn, Yongin-City (KR); Cheol-Ho Yu, Yongin-City (KR); Sung-Chul Kim, Yongin-City (KR)

(73) Assignee: SAMSUNG MOBILE DISPLAY CO., LTD., Yongin-City (KR)

(21) Appl. No.: 12/963,193

(22) Filed: Dec. 8, 2010

(30) Foreign Application Priority Data
Dec. 15, 2009 (KR) 10-2009-0124724

(51) Int. Cl. C23C 16/24; C23C 14/34; C23C 14/14

(52) U.S. Cl. 204/298.02; 118/719

(57) ABSTRACT

In an apparatus for fabricating a thin film transistor, amorphous silicon is deposited on a substrate in a first multi-chamber and is crystallized into polycrystalline silicon without using a separate process chamber or multi-chamber, and the substrate deposited with the amorphous silicon is loaded into a second multi-chamber for forming electrodes, thereby making it possible to minimize a characteristic deviation and improve fabrication process efficiency. The apparatus includes a first multi-chamber in which amorphous silicon is deposited on a substrate, a second multi-chamber in which electrodes are formed on the substrate, and a loading/unloading chamber interposed between the first multi-chamber and the second multi-chamber. The loading/unloading chamber includes a substrate holder on a lower side thereof and a power voltage supplier on an upper side thereof.

### CLAIM OF PRIORITY

This application makes reference to, incorporates the same herein, and claims all benefits accruing under 35 U.S.C. §119 from an application earlier filed in the Korean Intellectual Property Office on Dec. 15, 2009 and there duly assigned Serial No. 2009-124724.

### BACKGROUND OF THE INVENTION

1. Field of the Invention

The present invention relates generally to an apparatus for fabricating a thin film transistor which includes a plurality of multi-chambers. More particularly, the present invention relates to an apparatus for fabricating a thin film transistor in which amorphous silicon deposited on a substrate in a first multi-chamber is crystallized into polycrystalline silicon without using a separate process chamber or multi-chamber, and the substrate deposited with the amorphous silicon is loaded into a second multi-chamber for forming electrodes, thereby making it possible to minimize a characteristic deviation and improve fabrication process efficiency.

2. Description of the Related Art

Flat panel display devices have replaced cathode ray tube display devices due to their characteristics such as light weight and thin thickness, and typical examples thereof include liquid crystal display devices (LCDs) and organic light emitting diode display devices (OLEDs). In comparison with the LCDs, the OLEDs are excellent in luminance and viewing angle characteristics, and require no backlight, so that they can be realized as ultra thin displays.

These OLEDs are display devices using a phenomenon such that electrons and holes injected into an organic thin film through a cathode and an anode are recombined to form excitons, and thus light having a specific wavelength is emitted by the release of energy resulting from de-excitation of the excitons.

The OLEDs are classified into two types, a passive matrix type and an active matrix type, according to a driving type. The active matrix type OLEDs require two thin film transistors (TFTs) to drive an organic light emitting diode having the organic thin film, i.e. a driving transistor for applying driving current to the organic light emitting diode and a switching transistor for sending a data signal to the driving transistor and determining on/off of the driving transistor, so that fabrication thereof is complicated compared to the passive matrix type OLEDs.

The passive matrix type OLEDs are restricted in application fields of low resolution and small displays due to problems with resolution, an increase in driving voltage, and a decrease in material duration, whereas the active matrix type OLEDs can provide stable luminance due to a constant current supplied using switching and driving transistors located at each pixel of a display region, and can be implemented as a display having low power consumption, high resolution, and a large size.

The TFTs, including the switching and driving transistors, typically include a semiconductor layer, a gate electrode located on one side of the semiconductor layer for controlling a flow of the current, and source and drain electrodes connected to opposite ends of the semiconductor layer for conducting a predetermined current through the semiconductor layer. This semiconductor layer may be formed of polycrystalline silicon (poly-Si) or amorphous silicon (a-Si). Since the poly-Si has higher electron mobility than the a-Si, the poly-Si is mainly applied at present.

In this regard, in order to form the semiconductor layer of poly-Si, a method of forming an a-Si layer on a substrate and crystallizing the a-Si layer into a poly-Si layer using one of solid phase crystallization (SPC), rapid thermal annealing (RTA), metal induced crystallization (MIC), metal induced lateral crystallization (MILC), excimer laser annealing (ELA) crystallization, and sequential lateral solidification (SLS) crystallization is mainly used.

An apparatus for fabricating such TFTs is typically configured to perform each process using a multi-chamber having a plurality of process chambers in order to improve process efficiency and prevent a gate electrode, an a-Si layer, a source electrode, and a drain electrode from causing corrosion or characteristic variation by contact with external air. However, the apparatus including the multi-chamber must fabricate the TFT by depositing a-Si on a substrate, transferring the substrate deposited with the a-Si to a separate multi-chamber or a separate process chamber so as to crystallize the a-Si into p-Si, transferring the substrate having the p-Si to another chamber again, and forming insulating layers and electrodes. For this reason, the apparatus poses a risk that the TFT will undergo characteristic deviation resulting from continuous environment variation and transformation caused by transferring the substrate, and has a limitation in reduction of process time.

### SUMMARY OF THE INVENTION

The present invention provides an apparatus for fabricating a thin film transistor, which apparatus includes a plurality of multi-chambers and can reduce the total number of process chambers by changing the method of crystallizing amorphous silicon deposited on a substrate.

According to an exemplary embodiment, an apparatus for fabricating a thin film transistor includes a plurality of multi-chambers. Specifically, the apparatus includes a first multi-chamber in which amorphous silicon is deposited on a substrate, a second multi-chamber in which electrodes are formed on the substrate, and a loading/unloading chamber interposed between the first multi-chamber and the second multi-chamber. The loading/unloading chamber includes a substrate holder on a lower side thereof and a power voltage supplier on an upper side thereof.

Thus, the thin film transistor fabricating apparatus having the plurality of multi-chambers according to the invention employs the loading/unloading chamber between the first multi-chamber having the plurality of first process chambers for depositing the amorphous silicon on the substrate and the second multi-chamber having the plurality of second process chambers for forming the electrodes on the substrate so as to crystallize the amorphous silicon deposited in the first multi-chamber into the polycrystalline silicon. As a result, the total number of process chambers can be reduced so as to minimize a characteristic deviation and improve fabrication process efficiency.

Additional aspects and/or advantages of the invention will be set forth, in part, in the description which follows and, in part, will be obvious from the description, or may be learned by practice of the invention.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1A is a schematic diagram illustrating a part of an apparatus for fabricating a thin film transistor according to an embodiment of the invention;

FIG. 1B is a cross-sectional diagram taken along line I-I′ of FIG. 1A;

FIG. 2A is a perspective diagram illustrating a loading/unloading chamber interposed between a first multi-chamber and a second multi-chamber in an apparatus for fabricating a thin film transistor according to an embodiment of the invention;

FIG. 2B is a cross-sectional diagram taken along line A-A′ of FIG. 2A; and

FIG. 2C is a cross-sectional diagram taken along line B-B′ of FIG. 2A.

### DETAILED DESCRIPTION OF THE INVENTION

Reference will now be made in detail to the present invention, examples of which are shown in the accompanying drawings, wherein like reference numerals refer to the like elements throughout. In the drawings, the lengths and thicknesses of layers and regions may be exaggerated for clarity. The embodiments are described below in order to explain the present invention by referring to the figures.

The present invention is characterized by using a loading/unloading chamber between a first multi-chamber for depositing amorphous silicon (a-Si) on a substrate and a second multi-chamber for forming electrodes on the substrate as a crystallization unit which does not require a vacuum state, thereby reducing the total number of process chambers.

A crystallization method is disclosed in Korean Patent Application No. 2005-73706, in which an a-Si thin film is crystallized into a polycrystalline silicon (poly-Si) thin film using heat generated by Joule heating, i.e. by applying a predetermined power voltage to the a-Si thin film, so that a crystallization process can be performed without keeping a process chamber in a vacuum state.

In the present invention, a loading/unloading chamber between a first multi-chamber for depositing a-Si on a substrate and a second multi-chamber for forming electrodes on the substrate is subjected to Joule heating for a crystallization process so that the total number of process chambers is reduced.

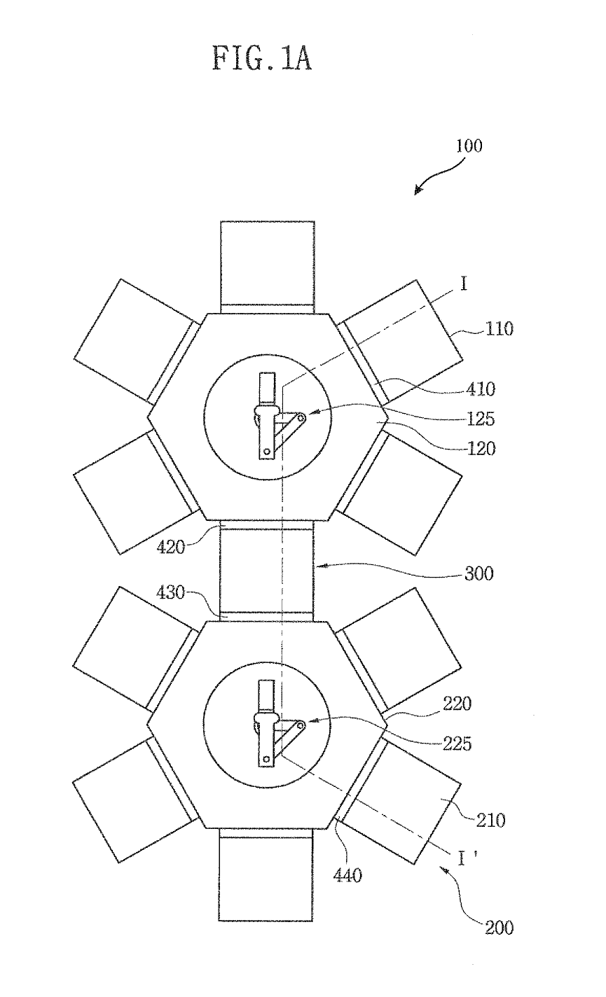

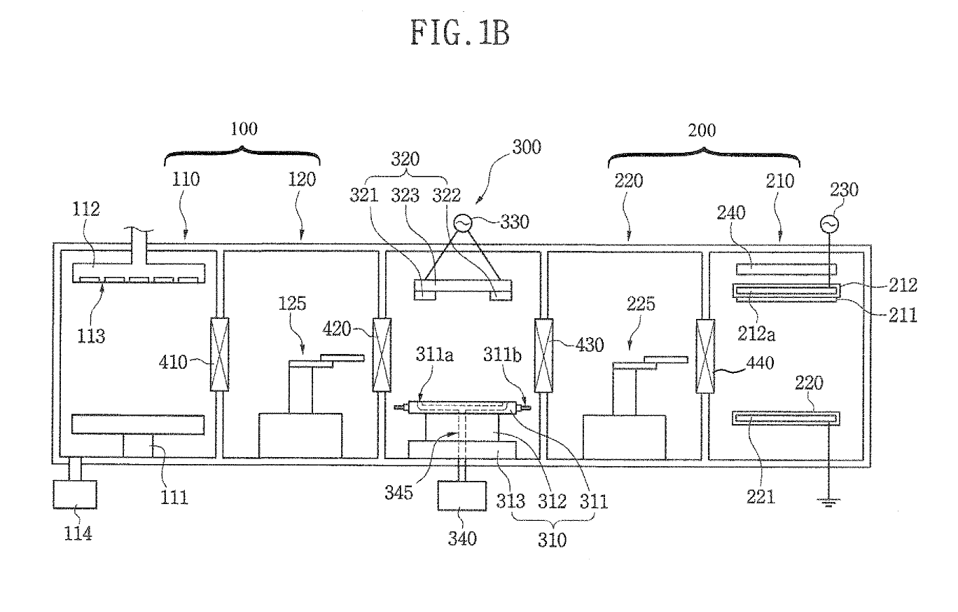

FIG. 1A is a schematic diagram illustrating a part of an apparatus for fabricating a thin film transistor according to an embodiment of the invention, while FIG. 1B is a cross-sectional diagram taken along line I-I′ of FIG. 1A.

Referring to FIGS. 1A and 1B, the apparatus for fabricating a thin film transistor according to the invention includes a first multi-chamber 100 having a plurality of first process chambers 110, a second multi-chamber 200 having a plurality of second process chambers 210, and a loading/unloading chamber 300 between the first multi-chamber 100 and the second multi-chamber 200.

The first multi-chamber 100 is provided to deposit a-Si on a substrate (not shown), and includes a plurality of first process chambers 110, and a first transfer chamber 120. A first robot arm 125 is disposed in the first transfer chamber 120 in order to load/unload the substrate into/from the plurality of first process chambers 110. In order to deposit the a-Si on the substrate, each of the first process chambers 110 includes a support chuck 111 for supporting the substrate, and a shower head 112 having a plurality of spray nozzles 113 for spraying a deposition material. Thus, an a-Si layer can be formed in the process chambers 110 by a deposition process.

The second multi-chamber 200 is provided in order to form electrodes on the substrate, and includes a plurality of second process chambers 210 and a second transfer chamber 220. A second robot arm 225 is disposed in the second transfer chamber 220 in order to load/unload the substrate into/from the plurality of second process chambers 210. Each of the second process chambers 210 includes a target 211, a target holder 212 having a first electrode 212a connected to a voltage source 230, a support 220 having a second electrode 221 connected to a reference voltage, and a magnet assembly 240 located to the rear of the target holder 212. Thus, an electrode layer can be formed in the process chambers 210 by a sputtering process.

In this regard, loading/unloading gates 410 and 440, each of which has a gate valve (not shown), are provided. Loading/unloading gate 410 is interposed between the first process chamber 110 and the first transfer chamber 120, and the loading/unloading gate 440 is interposed between the second process chamber 210 and the second transfer chamber 220, such that the first process chamber 110 and the second process chamber 210 can be kept in a vacuum state while performing the process.

The loading/unloading chamber 300 is provided to crystallize the a-Si, which is deposited on the substrate unloaded from the first multi-chamber 100, into poly-Si, and to load the substrate having the poly-Si into the second multi-chamber 200. The loading/unloading chamber 300 includes a substrate holder 310 located on a lower side thereof, and a power voltage supplier 320 located on an upper side thereof and having first and second electrodes 321 and 322 having different polarities.

In this regard, like the loading/unloading gates 410 and 440, loading/unloading gates 420 and 430, each of which has a gate valve, are provided. Loading/unloading gate 420 is interposed between the first transfer chamber 120 and the loading/unloading chamber 300, while the loading/unloading gate 430 is provided between the loading/unloading chamber 300 and the second transfer chamber 220, such that the first multi-chamber 100 and the second multi-chamber 200 can be kept in a vacuum state while performing the process.

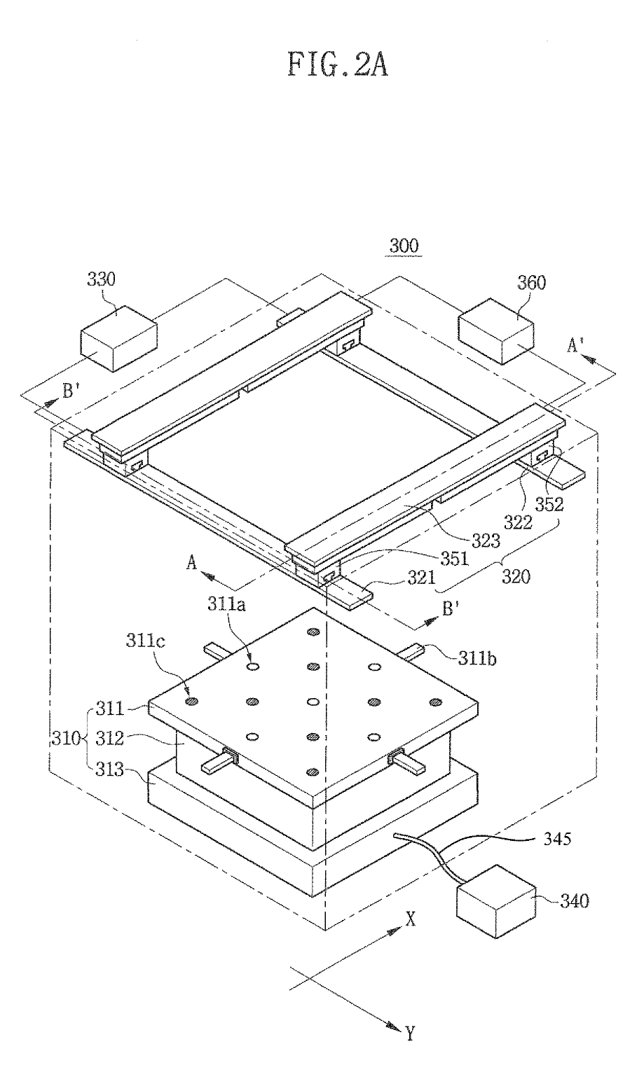

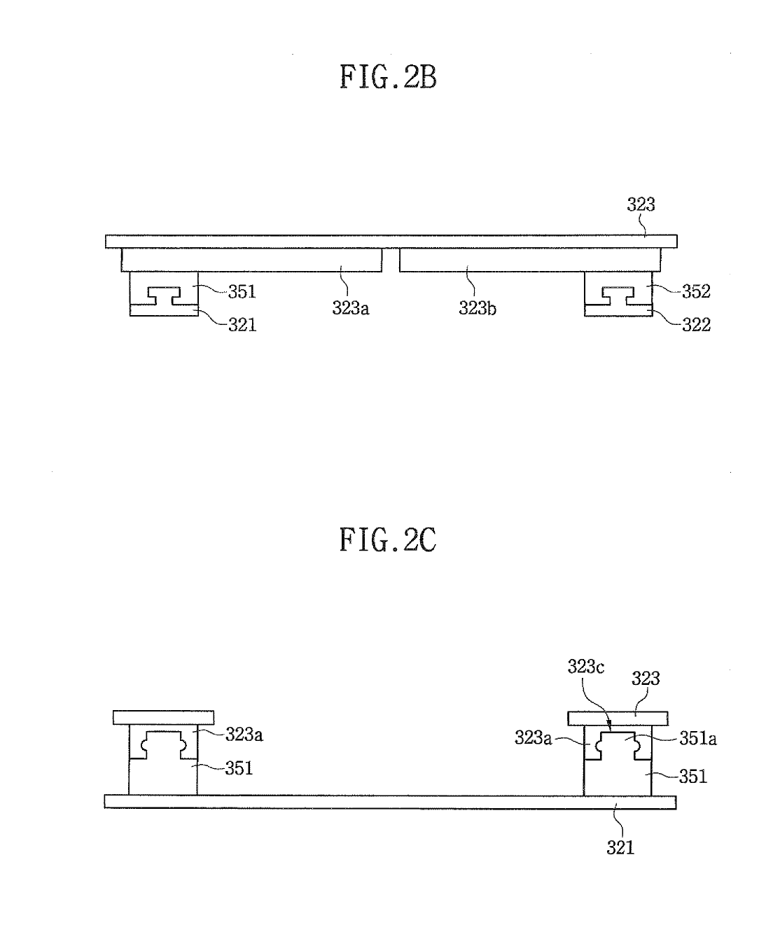

FIG. 2A is a perspective diagram illustrating a loading/unloading chamber interposed between a first multi-chamber and a second multi-chamber in an apparatus for fabricating a thin film transistor according to an embodiment of the invention; FIG. 2B is a cross-sectional diagram taken along line A-A′ of FIG. 2A; and FIG. 2C is a cross-sectional diagram taken along line B-B′ of FIG. 2A.

The loading/unloading chamber 300 of the apparatus for fabricating a thin film transistor according to an embodiment of the invention will be described in greater detail with reference to FIG. 2A thru 2C. The substrate holder 310 is provided to support the substrate loaded into the loading/unloading chamber 300, and moves the substrate to a position where power voltage can be applied by the power voltage supplier 320 such that the a-Si deposited on the substrate can be crystallized. The substrate holder 310 includes a substrate support 311 providing a space in which the substrate is placed, a holder elevator 312 for raising or lowering the substrate support 311, and a holder driver 313 for controlling the holder elevator 312.

The substrate support 311 may include a means for clamping the placed substrate. The clamping means may include one or more vacuum holes 311a for evacuating air located between the substrate and the substrate support 311 so as to cause the substrate to come into close contact with the substrate support 311. In this regard, the vacuum holes 311a are connected to a vacuum pump 340 through a vacuum pipe 345. Thus, the air between the substrate and the substrate support 311 is forcibly drawn through the vacuum holes 311a so that the substrate can come into close contact with the substrate support 311.

Furthermore, the substrate support 311 may include a means 311b for aligning the substrate, and a plurality of sensors 311c for detecting a size of the substrate. The aligning means 311b may be located on an outer circumference of the substrate support 311, and causes the substrate misaligned on the substrate support 311 to be aligned, for instance, by pushing the substrate into proper position.

The power voltage supplier 320 is provided in order to apply a constant power voltage to a conductive thin film of the substrate, and to crystallize the a-Si deposited on the substrate. The power voltage supplier 320 includes a first electrode 321, a second electrode 322, and a power voltage source 330 for applying power voltages having different polarities to the first and second electrodes 321 and 322, respectively.

In this regard, the power voltage supplier 320 may further include a controller 360 for adjusting an interval between the first electrode 321 and the second electrode 322 such that a constant power voltage can be applied to an accurate position of the substrate regardless of the size of the loaded substrate, and a mobile guide 323 for providing movement paths of the first and second electrodes 321 and 322, respectively, adjusted by the controller 360.

Furthermore, in order to easily adjust movement and alignment of the first and second electrodes 321 and 322, respectively, the power voltage supplier 320 may further include a first electrode transfer part 351 coupled between the first electrode 321 and the mobile guide 323 for moving the first electrode 321 under the control of the controller 360, and a second electrode transfer part 352 coupled between the second electrode 322 and the mobile guide 323 for moving the second electrode 322 under the control of the controller 360.

In this regard, the mobile guide 323 may include a first mobile guide 323a (see FIG. 2B or FIG. 2C) for providing the movement path of the first electrode transfer part 351, and a second mobile guide 323b for providing the movement path of the second electrode transfer part 352. To prevent collision between the first electrode 321 and the second electrode 322, the first mobile guide 232a is preferably spaced a predetermined distance apart from the second mobile guide 323b.

More preferably, the first and second mobile guides 323a and 323b, respectively, have a predetermined length in the same direction, and cause the first and second electrodes 321 and 322, respectively, to move in the same direction so that positions of the first and second electrodes 321 and 322, respectively, can be more easily adjusted.

The loading/unloading chamber 300 of the apparatus for fabricating a thin film transistor according to an embodiment of the invention may be configured such that the first and second mobile guides 323a and 323b, respectively, are provided with guide grooves 323c which have a predetermined length in a y-axial direction in order to provide firmer coupling between the first mobile guide 323a and the first electrode transfer part 351 and between the second mobile guide 232b and the second electrode transfer part 352, and the first and second electrode transfer parts 351 and 352, respectively, are provided with protrusions 351a corresponding to the guide holes 232c.

Consequently, in the thin film transistor fabricating apparatus having the plurality of multi-chambers according to an embodiment of the invention, the loading/unloading chamber 300 (FIG. 1) between the first multi-chamber 100 for depositing the a-Si on the substrate and the second multi-chamber 200 for forming the electrodes on the substrate is used as a crystallization unit using Joule heat. Thereby, the a-Si deposited in the first multi-chamber 100 is crystallized into the poly-Si without a separate multi-chamber or a process chamber, and the substrate is transferred to the second multi-chamber 200 for forming the electrodes, so that the total number of process chambers can be reduced.

Although an embodiment of the invention has been shown and described, it will be appreciated by those skilled in the art that changes may be made in this embodiment without departing from the principles and spirit of the invention, the scope of which is defined in the claims and their equivalents.

What is claimed is:

1. An apparatus for fabricating a thin film transistor, comprising:
a first multi-chamber in which amorphous silicon is deposited on a substrate;
a second multi-chamber in which electrodes are formed on the substrate; and
a loading/unloading chamber interposed between the first multi-chamber and the second multi-chamber;
wherein the loading/unloading chamber includes a substrate holder on a lower side thereof and a power voltage supplier on an upper side thereof.

2. The apparatus according to claim 1, wherein the substrate holder includes a substrate support for providing a space in which the substrate is placed, a holder elevator for raising and lowering the substrate support, and a holder driver for controlling the holder elevator.

3. The apparatus according to claim 2, wherein the substrate support includes means for clamping the substrate.

4. The apparatus according to claim 3, wherein the clamping means includes at least one vacuum hole connected to a vacuum pump.

5. The apparatus according to claim 2, further comprising means located on an outer circumference of the substrate support for aligning the substrate.

6. The apparatus according to claim 2, wherein the substrate support further includes at least one sensor for detecting a size of the substrate.

7. The apparatus according to claim 1, wherein the power voltage supplier includes a first electrode, a second electrode, and a power voltage source for applying power voltages having different polarities to the first and second electrodes.

8. The apparatus according to claim 7, wherein the power voltage supplier further includes a controller for adjusting an interval between the first electrode and the second electrode.

9. The apparatus according to claim 7, wherein the power voltage supplier further includes a first electrode transfer part for moving the first electrode, a second electrode transfer part for moving the second electrode, and a mobile guide for providing movement paths of the first and second electrode transfer parts.

10. The apparatus according to claim 9, wherein:
the mobile guide includes a first mobile guide for providing the movement path of the first electrode transfer part, and a second mobile guide for providing the movement path of the second electrode transfer part; and
the first mobile guide is spaced a predetermined distance apart from the second mobile guide.

11. The apparatus according to claim 10, wherein:
the first and second mobile guides include guide grooves formed in a lengthwise direction thereof; and
the first and second electrode transfer parts include protrusions corresponding to the guide holes.

12. The apparatus according to claim 1, wherein the second multi-chamber includes process chambers for performing a sputtering process.

13. The apparatus according to claim 1, further comprising gate valves installed between the first multi-chamber and the loading/unloading chamber, and between the loading/unloading chamber and the second multi-chamber.
